(19) United States
(12) Patent Application Publication
(10) Pub. No.: US 2013/0154061 A1
(43) Pub. Date: Jun. 20, 2013

(54) ANODIZING APPARATUS, AN ANODIZING SYSTEM HAVING THE SAME, AND A SEMICONDUCTOR WAFER

(71) Applicants: Dainippon Screen MFG. Co., Ltd., Kyoto (JP); Solexel, Inc., Milpitas, CA (US)

(72) Inventors: Noriyuki HAYASHI, Kyoto (JP); Yasuyoshi MIYAJI, Kyoto (JP); Seiichi YONEHARA, Kyoto (JP); Takamitsu INAHARA, Kyoto (JP); Takao YONEHARA, Milpitas, CA (US); Mehrdad MOSLEHI, Milpitas, CA (US); Subramanian TAMILMANI, Milpitas, CA (US); Karl-Josef KRAMER, Milpitas, CA (US); Jay ASHJAEE, Milpitas, CA (US)

(73) Assignees: SOLEXEL, INC., Milpitas, CA (US); DAINIPPON SCREEN MFG. CO., LTD., Kyoto (JP)

(21) Appl. No.: 13/688,645

(22) Filed: Nov. 29, 2012

(30) Foreign Application Priority Data
Nov. 30, 2011 (JP) JP2011-262421

(51) Int. Cl. C25D 17/00; H01L 29/06; H01L 21/02

(52) U.S. Cl. CPC C25D 17/001; H01L 21/02002; H01L 29/06
USPC 257/618; 204/275.1; 204/230.5; 204/269; 205/112

(57) ABSTRACT

An anodizing apparatus for causing an anodizing reaction to substrates immersed in an electrolyte solution. The apparatus includes a storage tank for storing the electrolyte solution, a holder for holding a plurality of substrates in liquid-tight contact with circumferential surfaces of the substrates, a moving mechanism for moving the holder between a transfer position outside the storage tank and a treating position inside the storage tank, and a closing device disposed in the storage tank for cooperating with the holder to complete a liquid-tight closure of the circumferential surfaces of the substrates held by the holder. Chemical reaction treatment is carried out with the circumferential surfaces of the substrates placed in a liquid-tight state. After the chemical reaction treatment is completed, the closing device is made inoperative and the holder is moved away from the treating position to unload the substrates from the storage tank.

### BACKGROUND OF THE INVENTION

(1) Field of the Invention

This invention relates to an anodizing apparatus for carrying out electrolytic etching treatment on various substrates, such as semiconductor wafers, substrates for liquid crystal displays, substrates for plasma displays, substrates for organic EL devices, substrates for FEDs (Field Emission Displays), optical disk substrates, substrates for magnetic disks, substrates for magnetic optical disks, substrates for photomasks, substrates for solar cells, substrates for micro-electro-mechanical systems (MEMS), semiconductor wafers for three-dimensional integrated circuits, substrates for opto-electronic integrated circuits, substrates for bioengineering, substrates for medical applications, substrates for optical waveguides, and substrates for artificial photosynthesis. More particularly, the invention relates to a batch processing technique for treating a plurality of substrates at the same time with high throughput.

(2) Description of the Related Art

Conventionally, an apparatus (first apparatus) of this type includes a fluororesin forming tank (2), a pair of platinum electrodes (3a, 3b), and a substrate support jig (4) for holding a substrate (1). See Japanese Unexamined Patent Publication H5-198556 (FIGS. 1 and 2), for example.

The fluororesin forming tank (2) stores an electrolytic solution (6a, 6b). The pair of platinum electrodes (3a, 3b) are arranged, as spaced from each other, inside the fluororesin forming tank (2). The substrate support jig (4) has an opening substantially corresponding to the outside diameter of the substrate (1), and has a cutout spreadable for inserting the substrate (1) into the substrate support jig (4). The jig (4) holds the substrate (1) through a seal (5a) to be liquid-tight with respect to the electrolytic solution (6a, 6b). The substrate support jig (4) is immersed along with the substrate (1) in the electrolytic solution (6a, 6b) in the fluororesin forming tank (2). When the pair of platinum electrodes (3a, 3b) are electrified, a chemical reaction starts to render the substrate (1) porous through the opening.

Another apparatus (second apparatus) of this type includes an electrolytic solution tank (11), a pair of electrodes (14A, 14B), and a substrate support member (15) for holding a substrate (5). See Japanese Unexamined Patent Publication No. 2003-45869 (FIGS. 1 and 3), for example.

The electrolytic solution tank (11) stores an electrolytic solution. The pair of electrodes (14A, 14B) are attached to opposite inner walls of the electrolytic solution tank (11). The substrate support member (15) has a first cassette (21) and a second cassette (22) for pinching the substrate (S) in between. The first cassette (21) has an opening (21A) substantially corresponding to the diameter of the substrate (S), and the second cassette (22) has a similar opening (22A). The first cassette (21) and second cassette (22) of the substrate support member (15) hold the substrate (S) in between, and engage the substrate (S) by pressing on peripheries of the substrate (S). The substrate support member (15) is inserted in a guide groove (16) of the electrolytic solution tank (11), and the pair of electrodes (14A, 14B) are electrified, thereby causing a chemical reaction to render the substrate (S) porous through the openings (21A, 22A).

However, the conventional examples with such constructions have the following problems.

In the first conventional apparatus, in order to make the substrate support jig (4) support the substrate (1), it is necessary to insert the substrate (1) in the opening after spreading the cutout of the substrate support jig (4). It is therefore difficult to make the substrate support jig (4) support the substrate (1) automatically by means of a mechanical device. When the apparatus is applied to batch processing for treating a plurality of substrates (1) at the same time, it becomes more difficult to automate the treatment in an effective way.

In the second conventional apparatus, in order to make the substrate support member (15) hold the substrate (S), it is necessary to place the substrate (S) to be pinched between the first cassette (21) and second cassette (22). Therefore, as with the first apparatus, there is a problem of being incapable of automating the treating process. Although the publication discloses an embodiment for treating two substrates (S), since the substrate support member (15) is constructed to have a considerable thickness, the apparatus is unsuitable for batch processing for treating an increased number of substrates (S).

### SUMMARY OF THE INVENTION

This invention has been made having regard to the state of the art noted above, and its object is to provide an anodizing apparatus well suited for automation and batch treatment, an anodizing system having the same, and a semiconductor wafer, which is achieved through an in-depth contemplation and study of a mechanism for holding substrates.

The above object is fulfilled, according to this invention, by an anodizing apparatus for causing an anodizing reaction to substrates immersed in an electrolyte solution, comprising a storage tank for storing the electrolyte solution; a holding device for holding a plurality of substrates in liquid-tight contact with circumferential surfaces of the substrates; a moving mechanism for moving the holding device between a transfer position outside the storage tank and a treating position inside the storage tank; and a closing device disposed in the storage tank for cooperating with the holding device to complete a liquid-tight closure of the circumferential surfaces of the substrates held by the holding device; wherein chemical reaction treatment is carried out with the circumferential surfaces of the substrates placed in a liquid-tight state by moving the holding device holding the substrates to the treating position, and operating the closing device, and after the chemical reaction treatment is completed, the closing device is made inoperative and the holding device is moved away from the treating position to unload the substrates from the storage tank.

According to this invention, when the moving mechanism moves the holding device to the treating position, with the holding device holding a plurality of substrates, and the closing device is operated, entire circumferential surfaces of the substrates are made liquid-tight with respect to the electrolyte solution inside the storage tank. After the chemical reaction treatment is carried out in this state, the closing device is made inoperative and the moving mechanism moves the holding device along with the plurality of substrates to the transfer position, thereby unloading the substrates from the storage tank. Therefore, the construction with the holding device cooperating with the closing device to maintain the substrates in the liquid-tight state, can mechanically load and unload the plurality of substrates into/from the storage tank. As a result, the anodizing apparatus well suited for automation and batch treatment can be realized.

In this invention, the holding device may be arranged to hold the substrates as aligned at predetermined intervals.

Since the plurality of substrates are aligned at predetermined intervals, the electrolyte solution flows in evenly between the substrates. Therefore, injection current density during the chemical reaction treatment becomes uniform for the respective substrates to realize uniform treatment of the substrates.

In this invention, the storage tank may have electrodes arranged adjacent one end and the other end in an aligning direction of the substrates held by the holding device, the electrodes being opposed to principal planes of substrates at opposite ends having the circumferential surfaces closed by the holding device and the closing device.

With the opposite electrodes at one end and the other end, the plurality of substrates can receive the chemical reaction treatment simultaneously.

In this invention, the holding device may include a first holder unit for contacting one side of the circumferential surfaces of the substrates, a second holder unit for contacting the other side of the circumferential surfaces of the substrates, and an opening and closing driver for moving the first holder unit and the second holder unit toward each other to hold the substrates, and moving the first holder unit and the second holder unit away from each other to release the substrates.

The opening and closing driver moves the first holder unit and the second holder unit toward and away from each other, thereby to hold the substrates and release the substrates.

In this invention, the closing device may have a closing member for contacting, in a liquid-tight state, parts of the circumferential surfaces of the substrates left out of contact with the holding device.

Since the closing member contacts, in a liquid-tight state, parts of the circumferential surfaces of the substrates not contacting the holding device, the closing member can complete a liquid-tight closure of the circumferential surfaces of the substrates. Therefore, the closing member can increase the degree of liquid-tightness of the circumferential surfaces of the substrates.

In this invention, the closing device may include a first closing member fixed inside the storage tank.

The first closing member fixed inside the storage tank, through cooperation with the holding device, can complete the liquid-tight closure of the circumferential surfaces of the substrates.

In this invention, the closing device may include a second closing member for pressing upon the circumferential surfaces of the substrates held by the holding device to maintain the liquid-tight state.

With the second closing member pressing upon the circumferential surfaces of the substrates held by the holding device, the degree of liquid-tightness of the circumferential surfaces of the substrates can be increased to complete the liquid-tightness of the circumferential surfaces of the substrates

In this invention, the holding device and the closing device may have elastic members as parts thereof for contacting the circumferential surfaces of the substrates.

The elastic members interposed can increase the degree of liquid-tightness of the circumferential surfaces of the substrates. This can minimize or eliminate leak current from the peripheries of the substrates, and can further uniform the current density over entire substrate surfaces of the formation current supplied thereto, which determines pore uniformity.

In this invention, the elastic members may have an electrical insulating property, and the parts for contacting the substrates may be formed uniformly over the entire circumferential surfaces of the substrates.

Since the elastic members are formed uniformly over the entire circumferential surfaces of the substrates, the electrolyte solution evenly contacts the front and back surfaces near the circumferential surfaces of the substrates. Further, since the elastic members have an insulating property, the chemical reaction treatment can be carried out uniformly over the entire surfaces excluding the circumferential surfaces of the substrates. Thus, using the highly insulating elastic members can minimize or eliminate leak current from the peripheries of the substrates, and can further uniform the current density over the entire substrate surfaces of the formation current supplied thereto, which determines pore uniformity. Particularly since the above holding device holds the circumferential surfaces (end surfaces) of the substrates to align and stand the substrates upright, there is no need to use lugs or the like to contact or press upon peripheral parts of the principal surfaces of the substrates. A high degree of symmetry and uniformity can be attained over entire areas on the principal surfaces of the substrates.

In this invention, each of the elastic members may have a two-layer structure including a first member located to face the circumferential surfaces of the substrates, and a second member located outside the first member, the first member having a smaller coefficient of elasticity than the second member.

Each of the elastic members has a two-layer structure and the first member is more easily deformable than the second member. Therefore, the first member can easily make close contact with the circumferential surfaces of the substrates to render the circumferential surfaces of the substrates liquid-tight reliably. With this construction, it is possible to control the regions around the end surfaces of the substrates sunk into the first elastic member, thereby to form porous layers on areas at a minimum distance to the end surfaces of the substrates.

In this invention, the anodizing apparatus may further comprise a pressing mechanism for pressing the second closing member upon the first holder unit and the second holder unit in the treating position.

The pressing mechanism which presses the second closing member upon the first holder unit and the second holder unit can increase the degree of liquid-tightness of the circumferential surfaces of the substrates. Thus, the circumferential surfaces of the substrates can be made liquid-tight reliably.

In this invention, the first holder unit and/or the second holder unit may have a first slope or slopes formed thereon and inclined outward and downward; the second closing member may have a second slope or slopes formed in a position or positions corresponding to the first slope or slopes and inclined outward and downward; and when the second closing member is pressed upon the first holder unit and/or the second holder unit in the treating position, the first slope or slopes and the second slope or slopes engage each other to push the first holder unit and the second holder unit toward each other.

When the second closing member is pressed upon the first holder unit and/or the second holder unit in the treating position, the first slope or slopes and the second slope or slopes engage each other to move the first holder unit and the second holder unit toward each other. Therefore, the first holder unit and the second holder unit can hold the substrates reliably.

In this invention, the first holder unit and/or the second holder unit may have a third slope or slopes formed thereon and inclined outward and upward; the first closing member may have a fourth slope or slopes formed in a position or positions corresponding to the third slope or slopes and inclined outward and upward; and when the second closing member is pressed upon the first holder unit and/or the second holder unit in the treating position, the first holder unit and/or the second holder unit is/are pressed upon the first closing member, and the third slope or slopes and the fourth slope or slopes engage each other to push the first holder unit and the second holder unit toward each other.

When the second closing member is pressed upon the first holder unit and/or the second holder unit in the treating position, the third slope or slopes and the fourth slope or slopes engage each other to move the first holder unit and the second holder unit toward each other. Therefore, the first holder unit and the second holder unit can hold the substrates reliably.

In this invention, each of the electrodes may be formed of highly compact, high-density, high-purity carbon.

It is desirable to use electrodes formed of highly compact, high-density, high-purity carbon from the point of view of preventing impurities mixing into the electrolyte solution, and of durability.

In this invention, the second closing member may have a plurality of exhaust passages formed between the substrates in plan view, and extending from an inner ceiling surface to an outer surface of the second closing member, with upper openings located above a liquid level in the storage tank; and the elastic member may have a plurality of elastic member passages formed in positions corresponding to the exhaust passages to communicate with the exhaust passages.

When the chemical reaction treatment generates gas which stagnates in bubbles in the interior of the second closing member, there occurs a possibility of causing reaction unevenness. However, since the second closing member has a plurality of exhaust passages and the elastic member has a plurality of elastic member passages, the gas generated does not stagnate in the second closing member, but is discharged outside. This prevents the treatment unevenness due to the bubbles.

In this invention, the second closing member may have an exhaust passage block between the inner ceiling surface and an upper surface of the elastic member; the exhaust passage block including a plate-like member having a plurality of block passages formed therein and communicating with the exhaust passages and the elastic member passages, and partitions formed on the plate-like member as arranged between the block passages and projecting toward the elastic member, with only lower ends of the partitions thrust into the elastic member.

Since the exhaust passage block includes a plate-like member having a plurality of block passages formed therein, and partitions arranged between the block passages, the exhaust passages of the second closing member are prevented from being closed by the elastic member even when the lower surface of the elastic member is pressed by upper circumferential surfaces of the substrates. Therefore, gas from the bubbles can be discharged through the exhaust passages reliably. This prevents treatment unevenness due to the bubbles.

In this invention, the anodizing apparatus may further comprise a switching circuit for alternately switching polarities of direct voltage to the electrode adjacent one end and the electrode adjacent the other end.

Since the switching circuit alternately switches polarities of direct voltage applied to the electrode adjacent one end and the electrode adjacent the other end, the chemical reaction treatment can be carried out on both surfaces of each substrate.

In this invention, the anodizing apparatus may further comprise an aligning rack for supporting the substrates as aligned parallel to one another; and an aligning rack moving mechanism for moving the aligning rack between the transfer position and an external transfer position different from the transfer position; wherein the moving mechanism transports the substrates to the storage tank after the holding device receives the substrates from the aligning rack in the transfer position.

By placing the substrates on the aligning rack, the substrates can be aligned parallel to one another. The substrates aligned are moved along with the aligning rack by the aligning rack moving mechanism between the transfer position and the external transfer position. The holding device can transport the substrates to the storage tank when the aligning rack has been moved to the transfer position. Thus, the substrates can be treated as aligned within the storage tank, and the chemical reaction treatment can be carried out on the substrates evenly.

In this invention, the anodizing apparatus may further comprise a cleaning mechanism disposed adjacent a moving path of the aligning rack moving mechanism for supplying a cleaning liquid to the substrates on the aligning rack in the moving path.

The cleaning mechanism disposed adjacent the moving path of the aligning rack moving mechanism can clean the substrates placed on the aligning rack during movement. This can improve the throughput of the treatment.

In another aspect of the invention, an anodizing system comprises the anodizing apparatus according to this invention; a standby tank disposed adjacent and upstream of the anodizing apparatus and having the aligning table; a loader disposed upstream of the standby tank for storing substrates to be treated; a cleaning tank disposed down-stream of the anodizing apparatus for cleaning the substrates having received chemical reaction treatment; a drying tank disposed downstream of the cleaning tank for drying the substrate cleaned; an unloader disposed down-stream of the drying tank for receiving the substrates treated; a first transport mechanism for transporting the substrates between the loader and the standby tank; a second transport mechanism having the holding device and the moving mechanism for transporting the substrates between the standby tank and the anodizing apparatus and between the anodizing apparatus and the cleaning tank; a third transport mechanism for transporting the substrates between the cleaning tank and the drying tank; and a fourth transport mechanism for transporting the substrates between the drying tank and the unloader.

The substrates to be treated and placed in the loader are transported by the first transport mechanism to the standby tank to be aligned therein. The substrates to be treated and placed in the standby tank are transported in an aligned state by the second transport mechanism to the anodizing apparatus. The substrates treated by the anodizing apparatus are transported by the second transport mechanism from the anodizing apparatus to the cleaning tank. The substrates cleaned in the cleaning tank are moved by the third transport mechanism from the cleaning tank to the drying tank. The substrates treated in the drying tank are transported by the fourth transport mechanism from the drying tank to the unloader. Thus, the plurality of substrates treated by the anodizing apparatus are efficiently transported to the subsequent tanks for treatment, thereby improving the throughput of the chemical reaction treatment.

In a further aspect of the invention, an anodizing system comprises a plurality of the anodizing apparatus according this invention; a loader disposed upstream of the plurality of the anodizing apparatus for storing substrates to be treated; a drying tank disposed downstream of the plurality of the anodizing apparatus for drying the substrates having received chemical reaction treatment and cleaned; an unloader disposed downstream of the drying tank for receiving the substrates treated; a first transport mechanism for transporting the substrates between the loader and each external transfer position; a second transport mechanism for transporting the substrates between the each external trans-fer position and the drying tank; and a third transport mechanism for transporting the substrates between the drying tank and the unloader.

A plurality of anodizing apparatus are juxtaposed, and a drying tank is disposed downstream of these anodizing apparatus. The substrates placed in the loader to be treated are transported by the first transport mechanism to each external transfer position, and receive the chemical reaction treatment in each anodizing apparatus. The substrates having received the anodizing treatment are cleaned by the cleaning mechanism, and then are trans-ported by the second transport mechanism to the drying tank. The substrates having received drying treatment are transported by the third transport mechanism to the unloader. Thus, large quantities of substrates can be treated with the plurality of anodizing apparatus, and since the substrates are efficiently transported to the next tank for treatment, the throughput of the chemical reaction treatment can be further improved.

In a still further aspect of this invention, an anodizing apparatus for causing an anodizing reaction to substrates immersed in an electrolyte solution, comprises a storage tank for storing the electrolyte solution; a holding device for forming a hollow portion therein having a section of similar shape to the substrates, and holding the substrates with circumferential surface of the respective substrates placed in a liquid-tight state; a pair of electrodes arranged at opposite ends of the hollow portion formed in the holding device; an electric circuit for applying direct current to the pair of electrodes; and a moving mechanism for moving the holding device between a transfer position outside the storage tank and a treating position inside the storage tank; wherein chemical reaction treatment is carried out with the circumferential surfaces of the substrates placed in the liquid-tight state and electrically separated and insulated, by moving the holding device holding the substrates to the treating position, and filling the hollow portion with the electrolyte solution, and after the chemical reaction treatment is completed, the holding device is moved from the treating position to unload the substrates from the storage tank.

According to this invention, the holding device holding a plurality of substrates is moved to the treating position, the hollow portion is filled with the electrolyte solution, and the chemical reaction treatment is carried out with the circumferential surfaces of the substrates made liquid-tight and electrically separated and insulated. After the chemical reaction treatment is completed, the holding device is moved from the treating position, thereby unloading the substrates from the storage tank. Therefore, by holding the substrates in the hollow portion of the holding device, the plurality of substrates can be mechanically loaded and unloaded into/from the storage tank. As a result, the anodizing apparatus well suited for automation and batch treatment can be realized.

This invention further provides a semiconductor wafer having porous layers of uniform thickness, pore size and pore density formed over both front and back surfaces of the semiconductor wafer, by carrying out anodizing treatment using the anodizing apparatus according to this invention.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a front view in vertical section showing an outline construction of an anodizing apparatus according to this invention;

FIG. 2 is a side view in vertical section showing the outline construction of the anodizing apparatus;

FIG. 3 is a plan view showing the outline construction of the anodizing apparatus;

FIGS. 4A-4B are front views showing outline constructions of a transport robot and a lower holder respectively;

FIG. 5 is a front view showing the outline construction of the lower holder;

FIG. 6 is a front view showing an outline construction of an upper holder;

FIG. 7 is a view partly in section of an upper holder unit, a left holder unit and the lower holder seen from the center;

FIG. 8 is a view in vertical section showing an outline construction of an exhaust mechanism;

FIG. 9 is a front view partly in section of an aligning rack;

FIGS. 10A-10B are explanatory views of operation at the time of transporting substrates from the aligning rack, in which FIG. 10A shows a state at the time of descent, and FIG. 10B shows a gripping state;

FIGS. 11A-11B are explanatory views of operation at the time of loading the substrates in a storage tank, wherein FIG. 11A shows a state at the time of descent, and FIG. 11B shows a closing state;

FIG. 12 is a plan view showing an outline construction of an anodizing system according to this invention;

FIG. 13 is a plan view showing an outline construetion of an anodizing system according to a different embodiment;

FIG. 14 is a schematic view showing the principle of making substrates porous by an anodizing apparatus; and

FIGS. 15A-15C are front views schematically showing a modified anodizing apparatus, wherein FIG. 15A shows left, right and upper holders shaped to match a circular wafer; and FIGS. 15B and 15C show holding devices with left and right holders adapted for polygonal and circular wafers, respectively.

### DESCRIPTION OF THE PREFERRED EMBODIMENTS

Preferred embodiments of this invention will be described in detail hereinafter with reference to the drawings.

<Anodizing Apparatus>

An anodizing apparatus according to this invention will be described hereinafter with reference to the drawings.

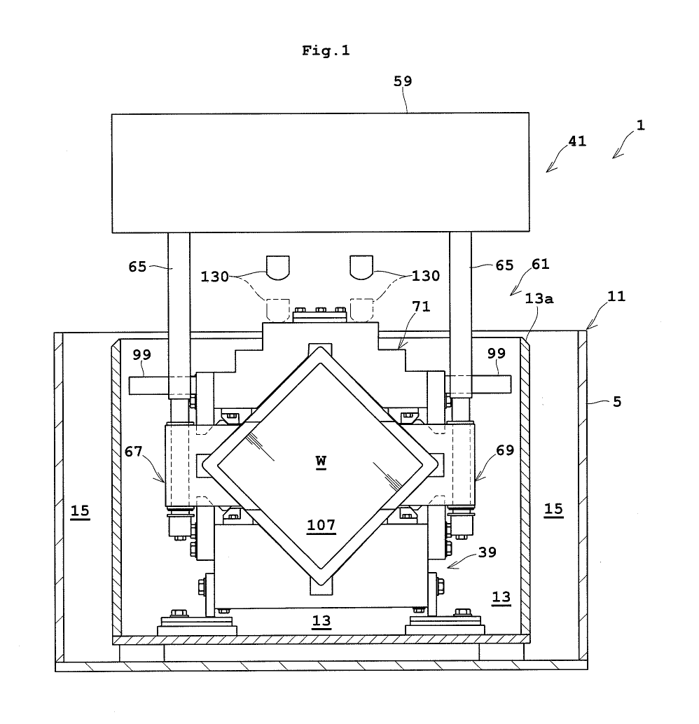

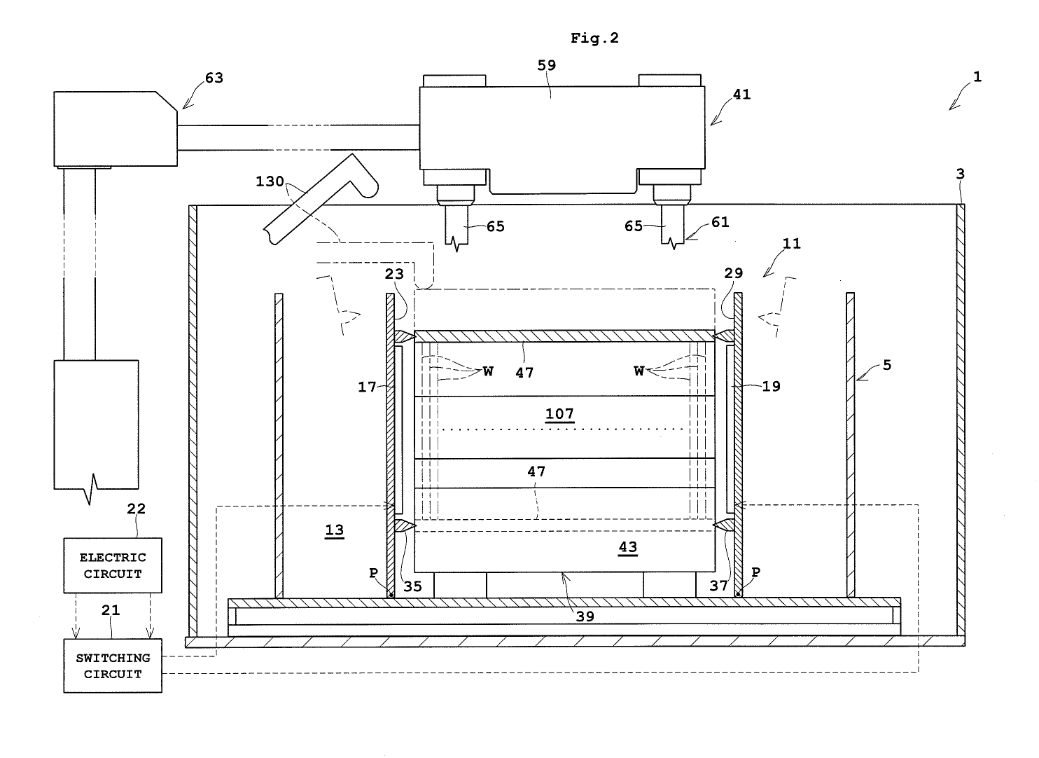

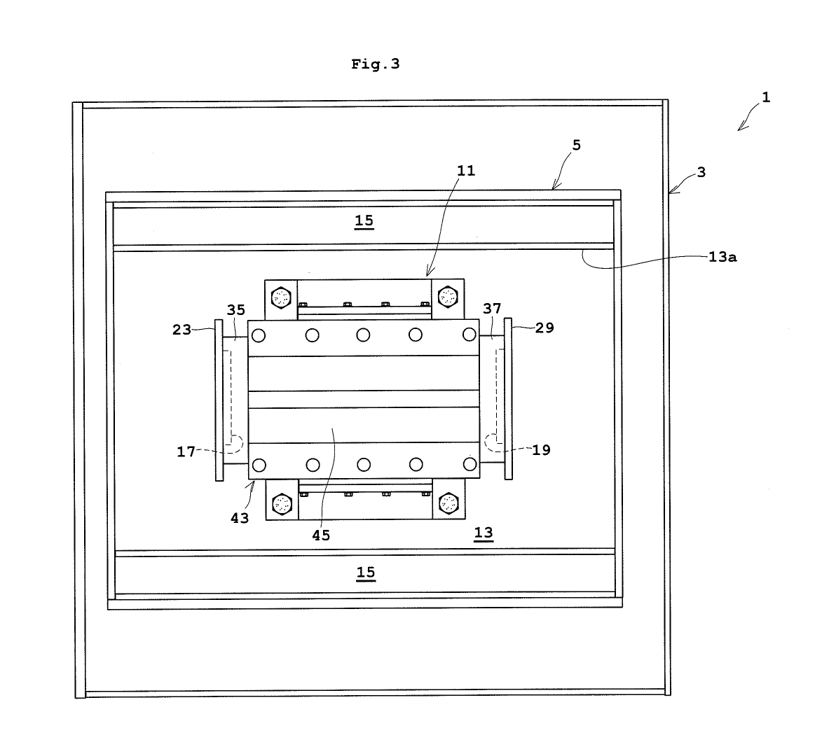

FIG. 1 is a front view in vertical section showing an outline construction of an anodizing apparatus according to this invention. FIG. 2 is a side view in vertical section showing the outline construction of the anodizing apparatus. FIG. 3 is a plan view showing the outline construction of the anodizing apparatus.

The anodizing apparatus 1 in this embodiment has a function for causing an anodizing reaction to a plurality of wafers W at the same time, thereby to treat silicon substrates to be porous, for example. This anodizing apparatus 1 includes an outer receptacle 3 and an inner receptacle 5. The inner receptacle 5 is disposed inside the outer receptacle 3. For convenience of illustration, the outer receptacle 3 is omitted from FIG. 1. This embodiment will be described taking square substrates as an example of wafers W.

The inner receptacle 5 has an inner tank 13 disposed inside, and outer tanks 15 are formed between the inner tank 13 and inner receptacle 5. The inner tank 13 and outer tanks 15 constitute a storage tank 11. The storage tank 11 stores an electrolyte solution. The electrolyte solution is a mixed solution, for example, of hydrofluoric acid solution, isopropyl alcohol and deionized water in a ratio of 1:1:1. The electrolyte solution is supplied from a weighing tank, not shown, to the bottom of the inner tank 13. The inner tank 13 is bounded by partitions 13a slightly lower than the inner receptacle 5 bounding the outer tanks 15, and the electrolyte solution overflowing the inner tank 13 is collected in the outer tanks 15.

The inner tank 13 has electrodes 17 and 19 disposed in positions therein immersed in the electrolyte solution.

As shown in FIG. 2, the electrodes 17 and 19 are electrically connected to a switching circuit 21 which alternately switches polarities of direct voltage in predetermined cycles. An electric circuit 22 is connected to the switching circuit 21 for applying the direct voltage to the pair of electrodes 17 and 19. Each of the electrodes 17 and 19, preferably, has a dual structure including a metal connected to the switching circuit 21, and a silicon substrate disposed on the side for contacting the electrolyte solution. The metal can be anything that has resistance to the electrolyte solution, such as platinum, palladium, gold, silver or copper, for example. The electrolyte solution includes hydrofluoric acid as noted above, and even if the metal has a certain level of resistance to hydrofluoric acid, metal components will be eluted. However, the dual structure with the silicon substrate disposed on the side for contacting the electrolyte solution can prevent the substrates under treatment from being contaminated by a different type metal.

Alternatively, carbon graphite can be used as electrodes 17 and 19. For example, carbon graphite having an impurity concentration of 5 ppm or less, which is obtained by filling cavities of common carbon graphite with high-purity carbon graphite to secure increased compactness and density, is desirable from the point of view of preventing impurities mixing into the electrolyte solution, and of durability.

As shown in FIG. 2, the electrodes 17 and 19 are attached to partitions 23 and 29 with an electrical insulating property, respectively. Further description will be made in this connection below. The partitions 23 and 29 are each pivotably attached to a shaft P provided in the bottom of the inner tank 13. The partitions 23 and 29 are arranged in the inner tank 13 to face wafers W at opposite ends of a plurality of wafers W held by an upper holder 61 when the upper holder 61 is located in a “treating position” as described hereinafter. The electrodes 17 and 19 are attached to surfaces facing the “treating position” of the partitions 23 and 29, respectively. The partition 23 has an annular lug 35 formed thereon to extend around the electrode 17. Similarly, the partition 29 has an annular lug 37 formed thereon to extend around the electrode 19. The annular lugs 35 and 37 are formed of a material with an electrical insulating property, and their inside diameter substantially corresponds to the inside diameter of a hollow portion 107 to be described hereinafter. The partitions 23 and 29 are rockable by a rocking mechanism not shown. When the wafers W are carried in and out, i.e. when the upper holder 61 loads and unloads the inner tank 13, the partitions 23 and 29 are rocked about the shafts P to open upper portions thereof away from each other as shown in two-dot chain lines in FIG. 2. This prevents interference with the loading and unloading action of the upper holder 61 described hereinafter. After the upper holder 61 moves to the treating position, the partitions 23 and 29 are rocked to move the upper portions thereof toward each other. As a result, tip ends of the annular lugs 35 and 37 thrust into an elastic member 47 described hereinafter, thereby to isolate the electrolyte solution in the hollow portion 107 and the electrolyte solution in the inner tank 13 from each other, and prevent movement of the electrolyte solutions between the two parts. This can prevent leakage from the hollow portion 107 and concentration variations of the electrolyte solution during treatment, thereby to prevent treating unevenness.

The inner tank 13 has a lower holder 39 disposed in the bottom thereof. This lower holder 39 is located in a position below the “treating position” of the wafers W. Above the lower holder 39 is a transport robot 41 which can transport the wafers W between the “treating position” corresponding to an upper part of the lower holder 39 and a “transfer position” outside the outer receptacle 3.

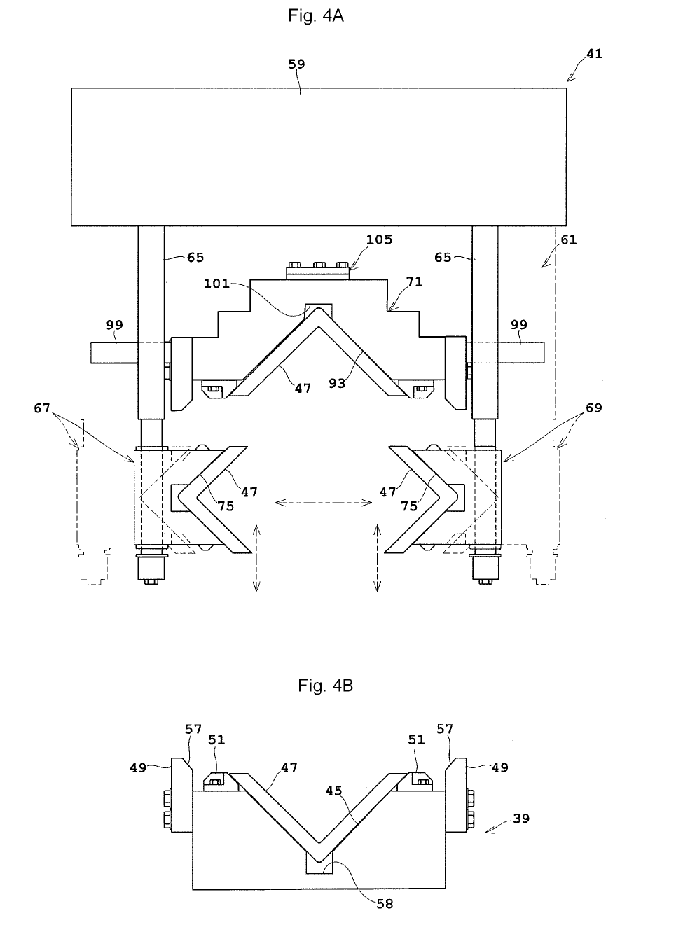

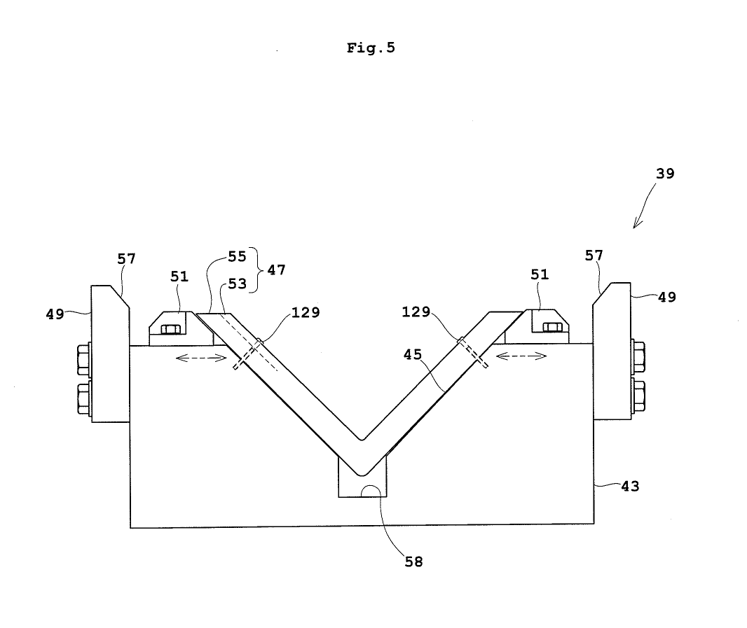

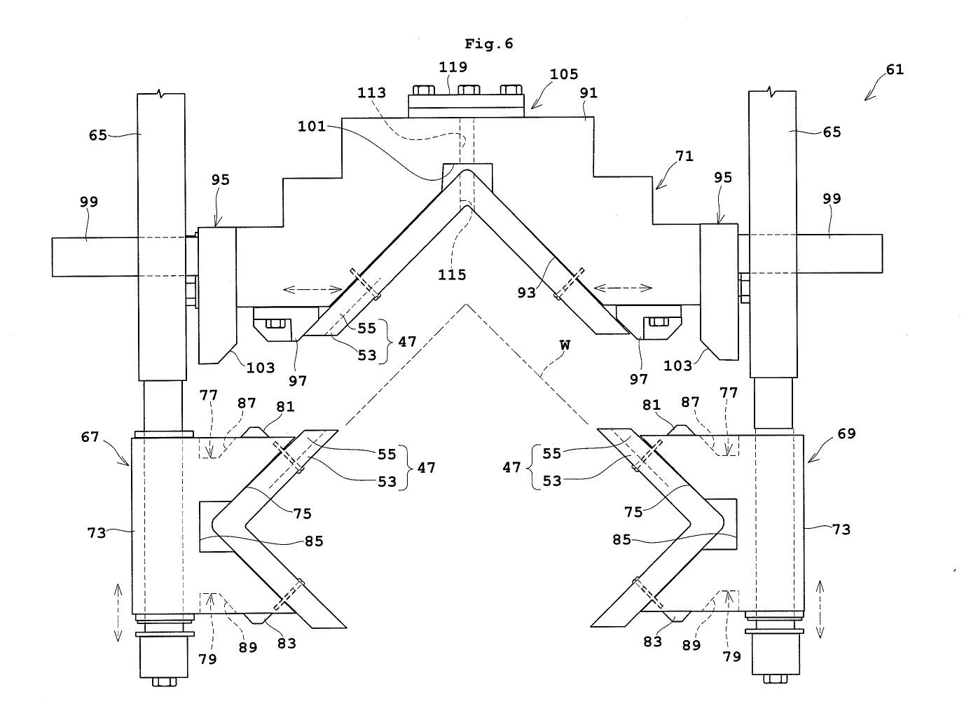

Reference is now made to FIGS. 4A-6. FIGS. 4A-4B are front views showing outline constructions of the transport robot and the lower holder, respectively. FIG. 5 is a front view showing an outline construction of the lower holder. FIG. 6 is a front view showing an outline construction of the upper holder.

Referring to FIG. 5, the lower holder 39 has a holder body 43, a V-groove 45, an elastic member 47, engaging members 49, and moving pieces 51. The holder body 43 is in form of a block and, as shown in FIG. 3, the V-groove 45 is formed in a middle region between short sides of the holder body 43 to extend along long sides of the holder body 43. The elastic member 47 is mounted in this V-groove 45 to extend along upper surfaces thereof, with opposite ends of the elastic member 47 projecting from upper parts of the V-groove 45. The engaging members 49 are attached to side surfaces of the holder body 43 in the transverse direction of the V-groove 45. The engaging members 49 project from upper surfaces of the holder body 43. The moving pieces 51 are mounted on the upper surfaces of the holder body 43 and laterally of the V-groove 45 to be movable horizontally.

The elastic member 47 may be formed of any material that has an electrical insulating property and is resistant to the electrolyte solution as well as being elastic. A specific material for the elastic member 47 is a foam product of a fluorinated material, for example. More particularly, ZOTEK (Registered Trademark) of Zotefoams plc may be mentioned. The elastic member 47, preferably, has a two-layer structure including, for example, a first member 53 located to face circumferential surfaces of the wafers W, and a second member 55 located outside the first member 53. Desirably, the first member 53 and second member 55 have different coefficients of elasticity, the first member 53 having a smaller coefficient of elasticity than the second member 55. That is, the first member 53, preferably, is softer than the second member 55. In a different definition, the first member 53, preferably, has less compression hardness than the second member 55. The first member 53 has a flat and uniform surface, with no groove or projection, which faces the circumferential surfaces of the wafers W. Therefore, there is no element inhibiting the electrolyte solution from flowing around to principal surfaces (front and back surfaces) of the wafers W which adjoin the circumferential surfaces of the wafers W. A uniform flow of formation electric current through the electrolyte solution is not checked, thereby to prevent treatment unevenness on the principal surfaces of the wafers W.

Since the elastic member 47 has a two-layer structure formed of the two types of members having different coefficients of elasticity as described above, when the wafers W are pinched, positions of the wafers W can be maintained stably and the circumferential surfaces of the wafers W can be made liquid-tight reliably. By appropriately selecting coefficients of elasticity of the two types of members, for example, setting can be made of a width (depth) of the edges of the wafers W forced on, thrusting into and making tight contact with the elastic member 47. The electrolyte solution does not act on the regions of the wafers W thrusting into and making tight contact with the elastic member 47, and porous layers are not formed on such portions. Therefore, a width of the portions with no formation of porous layers can be set arbitrarily by appropriately selecting materials, shapes, configurations and so on of the first member 53 and second member 55 to set the coefficients of elasticity. For example, it becomes possible to form the porous layers to areas closer to the edges of the substrates.

The elastic member 47 is mounted with a middle part of its outer surface inserted in a recess 58 formed in the middle part of the V-groove 45. Therefore, the elastic member 47 can have its inner surface shaped similar to corners of the square wafers W, thereby to improve the tight contact with the corners of the wafers W.

Each of the engaging members 49 attached to the opposite sides of the holder body 43 has a slope 57 formed on an upper inward part thereof and inclined outward and upward. These slopes 57 are engageable with lower engaging recesses 79 of a left holder unit 67 and a right holder unit 69 to be described hereinafter.

The pair of moving pieces 51 are mounted on the upper surfaces of the holder body 43, and outside opposite upper ends of the elastic member 47. These moving pieces 51 are movable between positions for pressing lateral surfaces of the portions of the elastic member 47 projecting from the upper surfaces of the holder body 43, and non-pressing positions. Such moving pieces 51 themselves do not have moving devices, but are moved by movement of lower pressing screws 83 of the left holder unit 67 and right holder unit 69 described hereinafter. Consequently, the opposite upper ends of the elastic member 47 are pressed toward the circumferential surfaces of the wafers W.

The lower holder 39 described above corresponds to the “closing device” and the “first closing device” in this invention. The slopes 57 described above correspond to the “fourth slopes” in this invention.

As shown in FIG. 2, the transport robot 41 includes a suspending mechanism 59, an upper holder 61 and a moving mechanism 63.

The suspending mechanism 59 has four suspension arms 65 extending downward. The upper holder 61 is supported by these suspension arms 65. The right and left suspension arms 65 are attached at upper parts thereof by the suspending mechanism 59 to be horizontally movable toward and away from each other as shown solid lines and two-dot chain lines in FIG. 4A. Their movement is effected by the suspending mechanism 59. The upper holder 61 is movable by the moving mechanism 63 between the “treating position” inside the inner tank 13 and the “transfer position” outside the outer receptacle 3. The moving mechanism 63 can move the upper holder 61 vertically and horizontally.

The upper holder 61 includes the left holder unit 67, the right holder unit 69 and an upper holder unit 71. The left holder unit 67, as seen from the front, contacts left circumferential surfaces of the wafers W. The right holder unit 69, as seen from the front, contacts right circumferential surfaces of the wafers W. Since the left holder unit 67 and right holder unit 69 have the same structure reversed right and left, the left holder unit 67 will be described hereinafter.

The left holder unit 67 is disposed on lower end regions of the suspension arms 65. However, the left holder unit 67 is attached to be vertically movable on the lower end regions of the suspension arm 65. A holder body 73 has an elastic member 47, a horizontal V-groove 75, an upper engaging recess 77, a lower engaging recess 79, an upper pressing screw 81 and a lower pressing screw 83. The elastic member 47 is mounted in the horizontal V-groove 75 to extend along side surfaces thereof, upper and lower ends of the elastic member 47 projecting sideways, and one upward and the other downward, from the horizontal V-groove 45. A recess 85 is formed in a middle part of the holder body 73, and the elastic member 47 is mounted with a middle part thereof inserted in the recess 85.

The upper engaging recess 77 is formed in an upper surface of the holder body 73 adjacent the suspension arms 65. The upper engaging recess 77 has a slope 87 formed on a side wall thereof adjacent the elastic member 47 and inclined outward and downward. The lower engaging recess 79 is formed in a lower surface of the holder body 73 adjacent the suspension arms 65. The lower engaging recess 79 has a slope 89 formed on a side wall thereof adjacent the elastic member 47 and inclined outward and upward.

The slope 87 described above corresponds to the “first slope” in this invention. The slope 89 corresponds to the “third slope” in this invention. The upper holder unit 71 described above corresponds to the “second closing member” in this invention.

The upper holder unit 71 has a holder body 91, an inverted V-groove 93, an elastic member 47, engaging members 95, moving pieces 97 and latch bars 99. The inverted V-groove 93 is formed in a lower surface of a middle region of the holder body 91. The elastic member 47 is mounted in this inverted V-groove 93 to extend along ceiling surfaces thereof, with opposite ends of the elastic member 47 projecting from lower parts of the inverted V-groove 93. A recess 101 is formed in the middle region of the holder body 91, and the elastic member 47 is mounted with a middle part thereof inserted in the recess 101.

The engaging members 95 are attached to opposite side surfaces of the holder body 71 to project from lower surfaces of the holder body 71. Each of the engaging members 95 has a slope 103 formed on a lower inward part thereof and inclined outward and downward. The engaging members 95 are mounted in positions corresponding to the upper engaging recesses 77 of the left holder unit 67 and right holder unit 69.

The pair of moving pieces 97 are mounted on the lower surfaces of the holder body 91, and outside opposite lower ends of the elastic member 47. These moving pieces 97 are movable between positions for pressing lateral surfaces of the portions of the elastic member 47 projecting from the lower surfaces of the holder body 91, and non-pressing positions. Such moving pieces 97 themselves do not have moving devices, but are moved by being pressed by the upper pressing screws 81 of the left holder unit 67 and right holder unit 69. Consequently, the opposite lower ends of the elastic member 47 are pressed toward the circumferential surfaces of the wafers W

The above upper holder unit 71 is only placed on the left holder unit 67 and right holder unit 69, and is not fixed to the left holder unit 67 or to the right holder unit 69. The upper holder unit 71 has a total of four latch bars 99 disposed laterally of the holder body 91, i.e. two each located on the right and left sides and between two front and back suspension arms 65 of the four suspension arms 65. These latch bars 99 are used to latch on to the wafers W temporarily when receiving the wafers W from an aligning rack 131 described hereinafter.

The above upper holder unit 71 has an exhaust mechanism 105 disposed on an upper part thereof. As shown in FIGS. 1 and 2, when the upper holder 61 and lower holder 39 are connected, a hollow portion 107 is formed as enclosed by the elastic members 47. In this hollow portion 107, bubbles are formed by anodizing reaction and gather in a ceiling part of the hollow portion 107 by buoyancy. These bubbles are discharged by the exhaust mechanism 105.

The upper holder 61, upper holder unit 71, left holder unit 67 and right holder unit 69 described above correspond to the “holding device” in this invention. The left holder unit 67 corresponds to the “first holder unit” in this invention. The right holder unit 69 corresponds to the “second holder unit” in this invention. The suspending mechanism 59 corresponds to the “opening and closing driver” in this invention. The slopes 103 correspond to the “second slopes” in this invention.

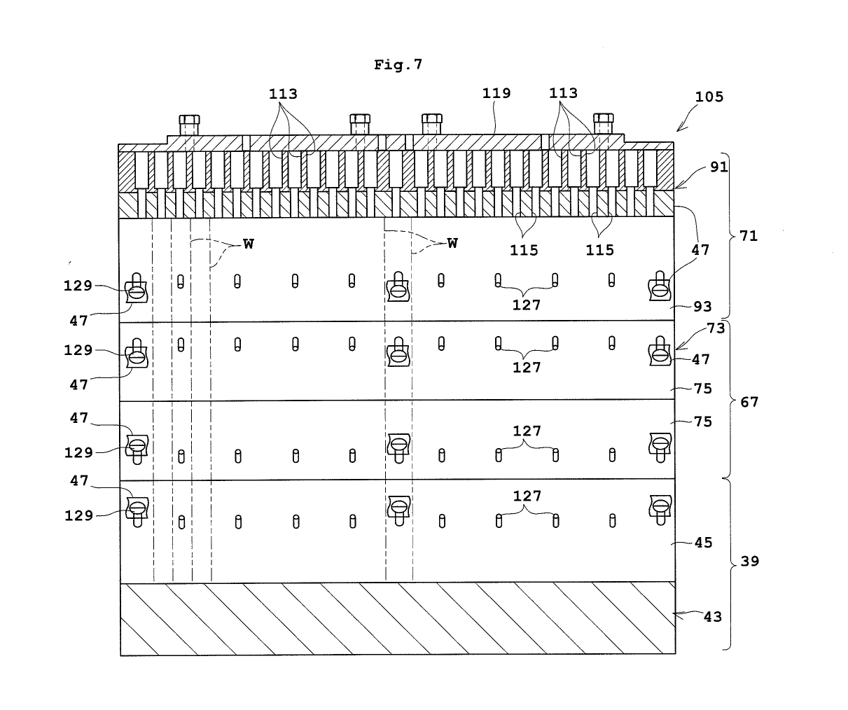

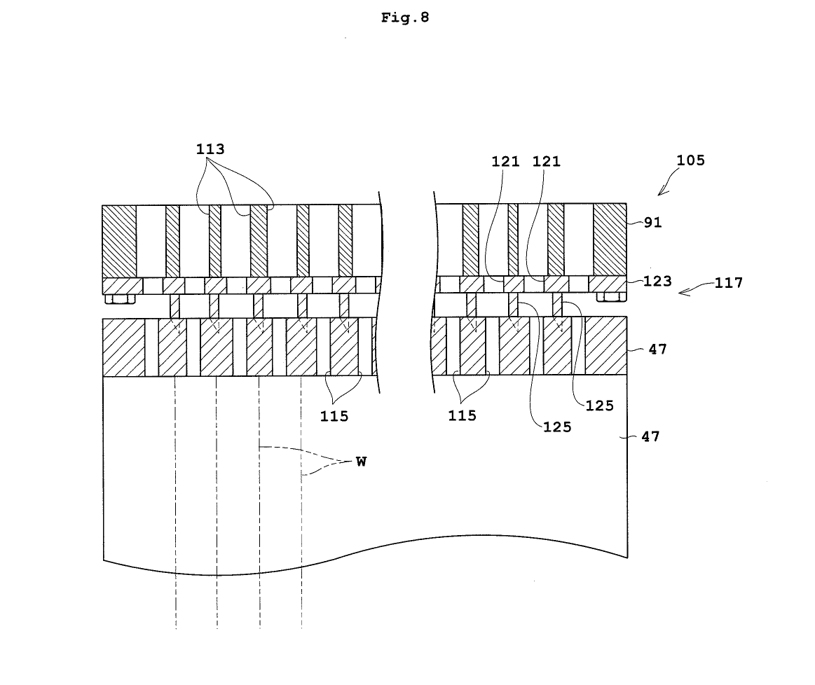

Reference is now made to FIGS. 7 and 8. FIG. 7 is a view partly in section of the upper holder unit, left holder unit and lower holder seen from the center. FIG. 8 is a view in vertical section showing an outline construction of the exhaust mechanism.

The exhaust mechanism 105 has a plurality of exhaust passages 113 and a plurality of elastic member passages 115. The exhaust passages 113 are formed to extend from an inner ceiling surface of the recess 101 in the holder body 91 of the upper holder unit 71 to an upper surface, and have upper openings located above a liquid level in the storage tank 11. The elastic member passages 115 are formed in the elastic member 47 of the upper holder unit 71. The elastic member passages 115 are formed in positions corresponding to, and in communication with, the respective exhaust passages 113. Each elastic member passage 115 is formed in a position between the wafers W held in place.

The exhaust mechanism 105 has an exhaust passage block 117 and a mounting member 119. The exhaust passage block 117 has a plurality of block passages 121, a plate-like member 123 and a plurality of partitions 125. The block passages 121 are formed in the plate-like member 123 to communicate with the exhaust passages 113. The partitions 125 are formed to project toward the elastic member 47 from between the block passages 121. The lower end of each partition 125 is thrust into the upper surface of the elastic member 47. The mounting member 119 is mounted on the upper surface of the holder body 91 for discharging gas from the exhaust passages 113.

As shown in FIG. 7, the above elastic members 47 are fixed to the holder body 91 of the upper holder unit 71, the holder body 73 of the left holder unit 67, and the holder body 43 of the lower holder 39 with a plurality of pins 127 made of resin and mounting screws 129. The pins 127 are formed to project from the surfaces of the V-groove 45, horizontal V-groove 75 and inverted V-groove 93. The pins 127 are thrust into, without penetrating, the elastic member 47. The mounting screws 129 are attached to extend from the surfaces of the elastic members 47, in positions deviating from holding positions of the wafers W. Therefore, the elastic members 47 are flat and uniform over the entire circumferential surfaces of the wafers W. This allows the electrolyte solution to flow uniformly to the front and back surfaces of the wafers W, and besides avoids treatment unevenness without inhibiting injection of the formation electric current.

As shown in FIG. 1, the storage tank 11 has pressurizing arms 130. When the above upper holder 61 has moved to the treating position (FIG. 1), the pressurizing arms 130 press on the upper surface of the upper holder unit 71, and through the upper holder unit 71, press the left holder unit 67 and right holder unit 69 toward the lower holder 39.

The above pressurizing arms 130 correspond to the “pressing mechanism” in this invention.

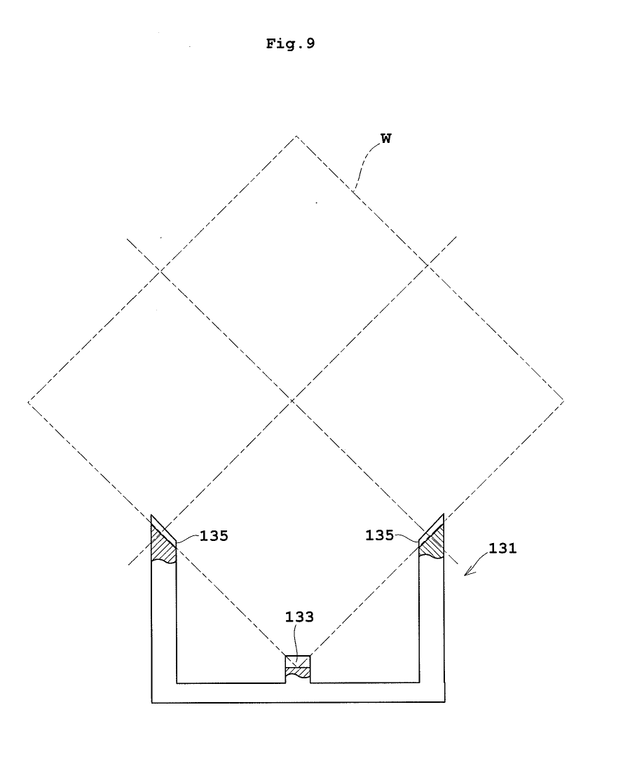

Next, reference is made to FIG. 9. FIG. 9 is a front view partly in section of the aligning rack.

The aligning rack 131 is disposed in the transfer position of the transport robot 41 noted hereinbefore. The aligning rack 13 has apex holders 133 and pairs of side holders 135. The aligning rack 131, with these holders, holds the square wafers W each to have one pair of corners vertically opposed to each other and the other pair of corners horizontally opposed. The side holders 135 hold the wafers W by contacting middle positions of the sides facing down. The apex holders 133 and side holders 135, respectively, are arranged at predetermined intervals in a direction perpendicular to the plane of FIG. 9.

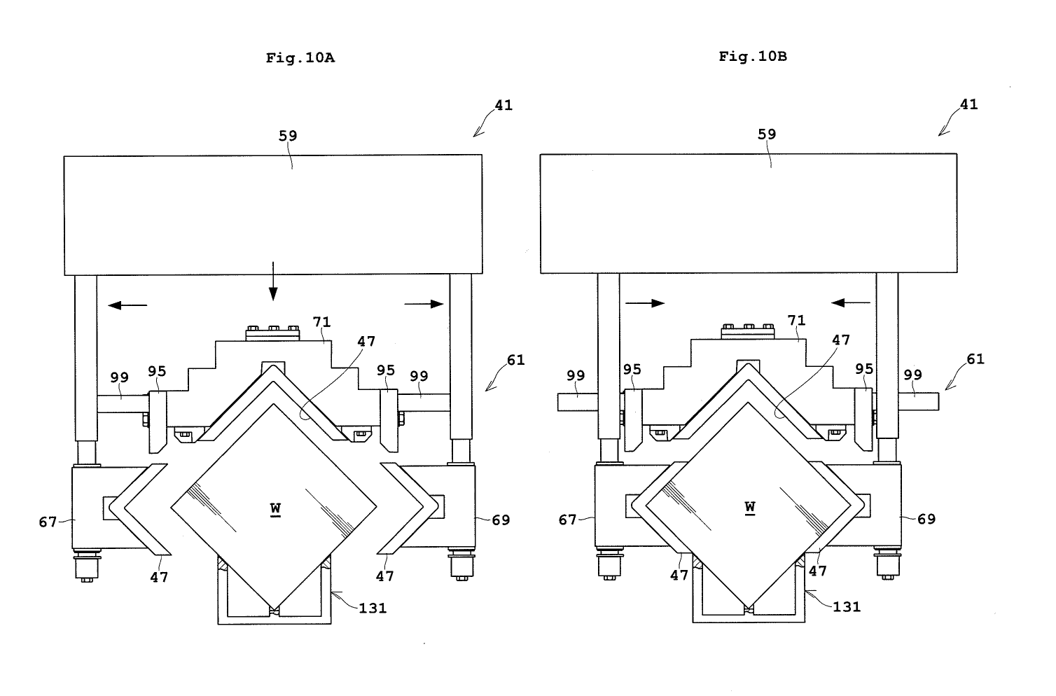

Next, reference is made to FIGS. 10A-10B, which present an explanatory view of operation at the time of transporting substrates from the aligning rack, in which FIG. 10A shows a state at the time of descent, and FIG. 10B shows a gripping state.

First, the moving mechanism 63 positions the suspending mechanism 59 above the aligning rack 131. Then, the suspension arms 65 are moved toward the ends to move the left holder unit 67 and right holder unit 69 away from each other. Next, the suspending mechanism 59 is lowered to move the upper holder 61 toward the aligning rack 131 (FIG. 10A). At this time, the left holder unit 67 and right holder unit 69 are separated far from each other to be clear of the corners of the wafers W. The latch bars 99 are latched by a latching device, not shown, at the time of descent, and the upper holder unit 71 stops in a position spaced from the corners of the wafers W. Therefore, no load is applied to the wafers W to prevent damage to the wafers W. Then, the suspension arms 65 are moved toward the center, to move the left holder unit 67 and right holder unit 69 toward each other, thereby to grip the pairs of corners present in the horizontal direction of the wafers W (FIG. 10B).

Next, the suspending mechanism 59 is raised. Then, the upper holder unit 71 located upward connects the left holder unit 67 and right holder unit 69. At this time, the engaging members 95 fit into the upper engaging recesses 77. Then, the slopes 103 of engaging members 95 and the slopes 87 of upper engaging recesses 77 slide relative to each other, and press the left holder unit 67 and right holder unit 69 toward the center of the wafers W. Therefore, the circumferential surfaces of the wafers W are reliably maintained liquid-tight. At this time, the moving pieces 97 are moved toward the center by the upper pressing screws 81, which press the ends of the elastic member 47 of the upper holder unit 71 upon the ends of the elastic member 47 of the left holder unit 67 and of the elastic member 47 of the right holder unit 69. Therefore, the elastic members 47 are joined tight together to render the circumferential surfaces of the wafers W liquid-tight reliably.

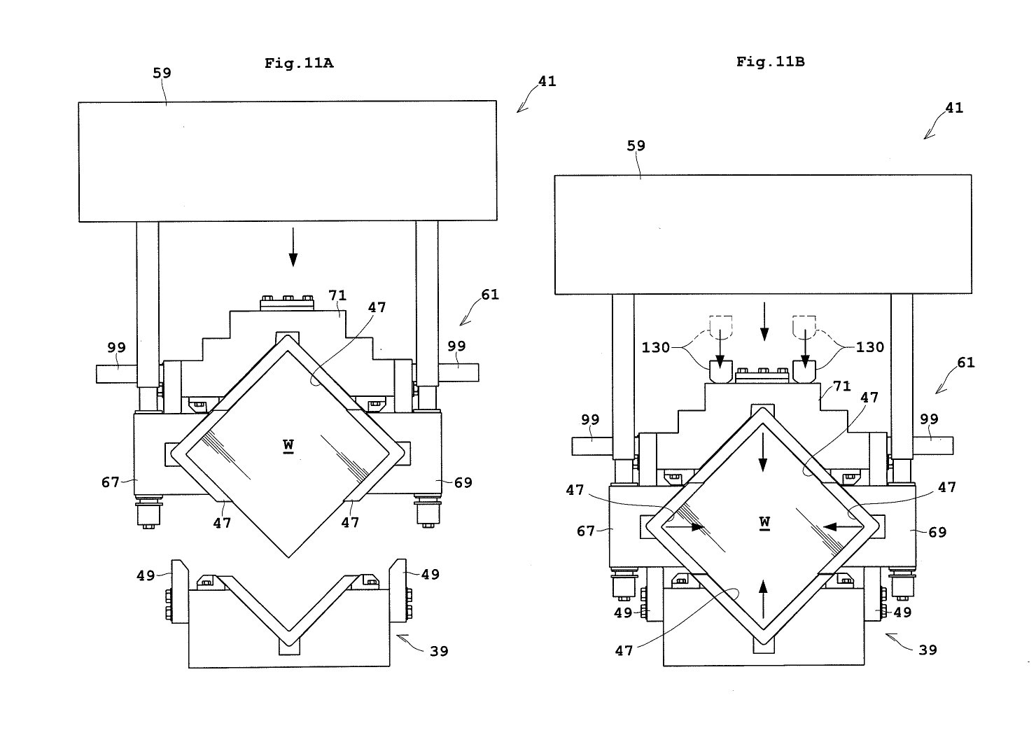

Next, reference is made to FIGS. 11A-11B, which present an explanatory view of operation at the time of loading the substrates in the storage tank, wherein FIG. 11A shows a state at the time of descent, and FIG. 11B shows a closing state. At this time (at the time of the loading the wafers W), the partitions 23 and 29 have been rocked about the shafts P to open the upper portions thereof away from each other as shown in two-dot chain lines in FIG. 2.

The moving mechanism 63 moves the suspending mechanism 59 to a position above the storage tank 11 storing the electrolyte solution noted hereinbefore. Then, the upper holder 61 is lowered toward the lower holder 39 in the inner tank 13 (FIG. 11A). At this time, upper parts and lower parts of the wafers W held by the upper holder 61 are not closed, and the electrolyte solution flows into and fills spaces between the wafers W. The descent is stopped when the lower corners of the wafers W contact the elastic member 47 of the lower holder 39 (FIG. 11B). At this time, the engaging members 49 of the lower holder 39 fit into the lower engaging recesses 79 of the left holder unit 67 and right holder unit 69. Then, the slopes 57 of engaging members 95 and the slopes 89 of the left holder unit 67 and right holder unit 69 slide relative to each other, and press the left holder unit 67 and right holder unit 69 toward the center of the wafers W. Therefore, the circumferential surfaces of the wafers W are reliably maintained liquid-tight. At this time, the moving pieces 51 are moved toward the center by the lower pressing screws 83, which press the ends of the elastic member 47 of the lower holder 39 upon the ends of the elastic member 47 of the left holder unit 67 and of the elastic member 47 of the right holder unit 69. Therefore, the elastic members 47 are joined tight together to render the circumferential surfaces of the wafers W liquid-tight reliably. The position of the upper holder 61 at this time is the treating position.

Further, the pressurizing arms 130 are operated to press the upper holder unit 71 upon the left holder unit 67 and right holder unit 69. Thus, the upper holder unit 711, left holder unit 67 and right holder unit 69 are pressed upon the lower holder 39. As a result, each elastic member 47 is stuck toward central parts of the wafers W, whereby the entire circumferential surfaces of the wafers W are firmly maintained in a liquid-tight state. Consequently, in the hollow portion 107 formed by the upper holder 61 and lower holder 39, the electrolyte solution having flowed in between the wafers W being held is isolated, and also electrically insulated, from the electrolyte solution in the inner tank 13 and outside the hollow portion 107.

At this time, further, the partitions 23 and 29 are rocked to close the upper portions of the partitions 23 and 29 toward each other. Consequently, the tip ends of the annular lugs 35 and 37 thrust into the elastic members 47 of the upper holder 61 and lower holder 39. This isolates also the electrolyte solution between the electrodes 17 and 19 and the wafers W at the opposite ends of the plurality of wafers W being held, from the electrolyte solution in the inner tank 13 present outside.

A plurality of wafers W are moved to the treating position in the inner tank 13 of the storage tank 11 as described above, and the electrolyte solutions inside and outside the hollow portion 107 electrically insulated. In this state, a predetermined voltage is applied from the electric circuit 22, and its polarities are switched in predetermined cycles by the switching circuit 21. Then, for the plurality of wafers W in the hollow portion 107, a circuit is formed from the electrode 17 through the electrolyte solution, wafer W, electrolyte solution, wafer W . . . , electrolyte solution, wafer W and electrolyte solution to the electrode 19. The current flowing therethrough produces an anodizing reaction on the front and back surfaces, excluding the circumferential surfaces, to render the wafers W porous. No reaction takes place on the circumferential surfaces of the wafers W in tight contact with the elastic members 47 and thus out of contact with the electrolyte solution, and these surfaces do not become porous. Since the plurality of wafers W are loaded into the storage tank 1 as aligned at the predetermined intervals on the aligning rack 131, chemical reaction treatment can be performed uniformly on the respective wafers W.

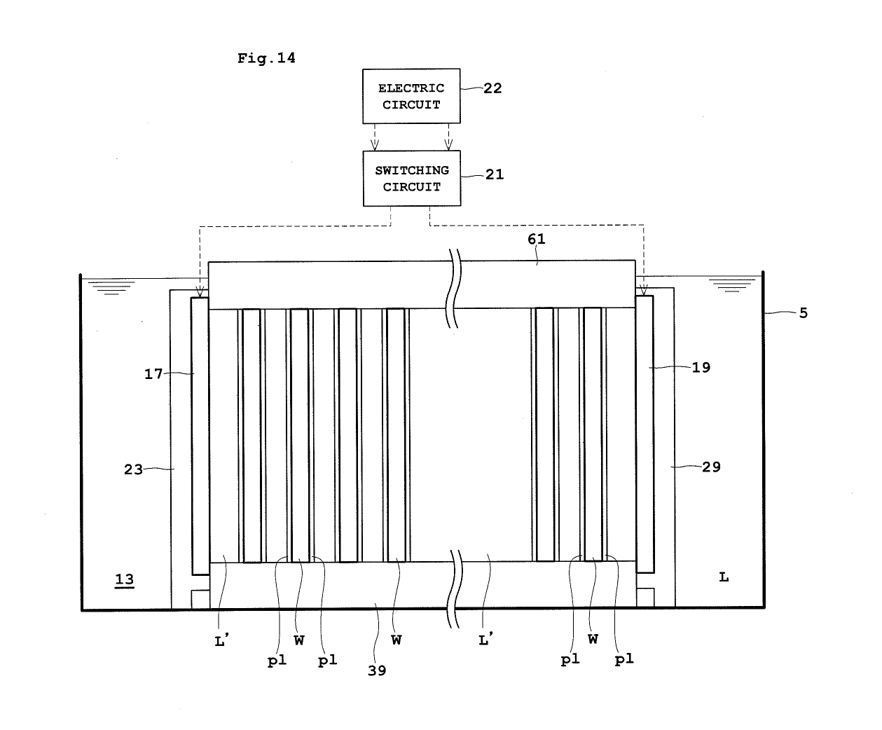

FIG. 14 is a view schematically showing how this treatment is performed. The electrolyte solution L′ in the hollow portion 107 closed by the electrodes 17 and 19 and partitions 23 and 29 at the opposite ends is completely isolated from the electrolyte solution L outside the hollow portion 107. Each part of the electrolyte solution L′ present in a gap between adjoining wafers W is isolated, and also electrically insulated, from the electrolyte solution L′ present in the other gaps. When electric current is supplied from the electric circuit 22 and switching circuit 21 in this state, the current will flow uniformly to all the wafers W in the hollow portion 107, and uniform porous layers pl will be formed on the front surfaces and back surfaces of all the wafers W. The porous layers pl formed here, although covering the front and back surfaces of the wafers W, have the same uniformity and symmetric property. Formation of such porous layers pl has never been realized in the past.

After a predetermined time of anodizing reaction, the plurality of wafers W are delivered to the aligning rack 131 by following the opposite of the transporting procedure described above. Consequently, the plurality of wafers W can be made porous, and moreover porous layers can be formed in a uniform thickness, pore size and pore density on both surfaces of the wafers W.

In the anodizing apparatus 1 according to the foregoing embodiment, the moving mechanism 63 moves the left holder unit 67 and right holder unit 69 to the treating position, with the left holder unit 67 and right holder unit 69 holding a plurality of wafers W. When the left holder unit 67 and right holder unit 69 are connected to the upper holder unit 71 and lower holder 39, entire circumferential surfaces of the wafers W are made liquid-tight with respect to the electrolyte solution inside the storage tank 11. After chemical reaction treatment is carried out in this state, the plurality of wafers W are unloaded from the storage tank 11 by disconnecting the upper holder unit 71 and lower holder 39 from the left holder unit 67 and right holder unit 69, and operating the moving mechanism 63 to move the left holder unit 67 and right holder unit 69 along with the plurality of wafers W to the transfer position. Therefore, the construction with the left holder unit 67 and right holder unit 69 cooperating with the upper holder unit 71 and lower holder 39 to maintain the wafers W in the liquid-tight state, can mechanically load and unload the plurality of wafers W into/from the storage tank 11. As a result, the anodizing apparatus 1 well suited for automation and batch treatment can be realized.

<Anodizing System 1>

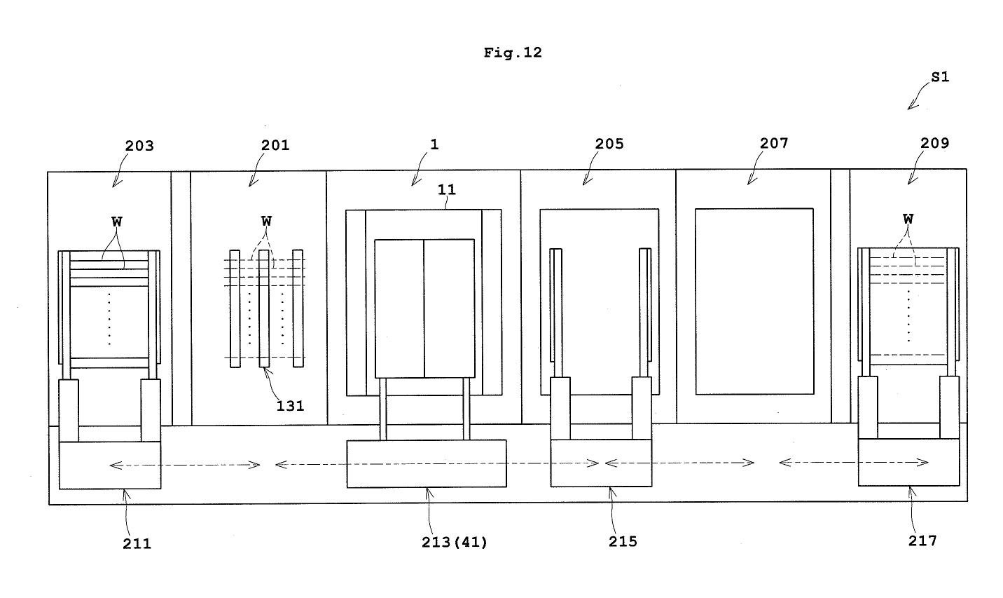

Next, an anodizing system S1 including the above anodizing apparatus 1 will be described with reference to FIG. 12. FIG. 12 is a plan view showing an outline construction of an anodizing system according to this invention.

This anodizing system S1 includes a standby tank 201 disposed adjacent and upstream of the anodizing apparatus 1 and having the aligning rack 131, a loader 203 disposed upstream of the standby tank 201 for storing wafers W to be treated, a cleaning tank 205 disposed down-stream of the anodizing apparatus 1 for cleaning the wafers W having received the chemical reaction treatment, a drying tank 207 disposed downstream of the cleaning tank 205 for drying cleaned wafers W, an unloader 209 disposed down-stream of the drying tank 207 for receiving treated wafers W, a first transport mechanism 211 for transporting the wafers W between the loader 203 and the standby tank 201, a second transport mechanism 213 for transporting the wafers W between the standby tank 201 and the anodizing apparatus 1 and between the anodizing apparatus 1 and the cleaning tank 205, a third transport mechanism 215 for transporting the wafers W between the cleaning tank 205 and the drying tank 207, and a fourth transport mechanism 217 for transporting the wafers W between the drying tank 207 and the unloader opener 209.

The second transport mechanism 213 is the transport robot 41 noted hereinbefore.

According to the anodizing system S1 having such construction, the wafers W to be treated and placed in the loader 203 are transported by the first transport mechanism 211 to the standby tank 210 to be aligned therein. The wafers W to be treated and placed in the standby tank 210 are transported in an aligned state by the second transport mechanism 213 to the anodizing apparatus 1. The wafers W treated by the anodizing apparatus 1 are transported by the second transport mechanism 213 from the anodizing apparatus 1 to the cleaning tank 205. The wafers W cleaned in the cleaning tank 205 are moved by the third transport mechanism 215 from the cleaning tank 205 to the drying tank 207. The wafers W treated in the drying tank 207 are transported by the fourth transport mechanism 217 from the drying tank 207 to the unloader 209. Thus, the plurality of wafers W treated by the anodizing apparatus 1 are efficiently transported to the subsequent tanks for treatment, thereby improving the throughput of the chemical reaction treatment.

<Anodizing System 2>

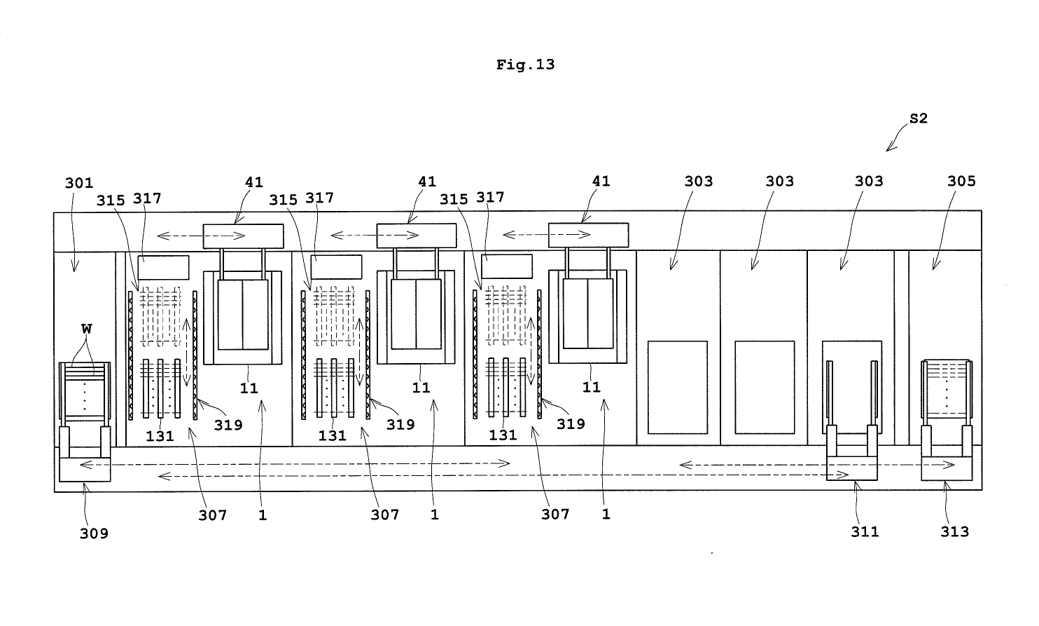

Next, an anodizing system S2 including the above anodizing apparatus 1 will be described with reference to FIG. 13. FIG. 13 is a plan view showing an outline construction of an anodizing system according to another embodiment.

This anodizing system S2 includes three anodizing apparatus 1 as described above which are juxtaposed, for example, a loader 301 disposed upstream of the three anodizing apparatus 1 for storing wafers W to be treated, three drying tanks 303 juxtaposed downstream of the three anodizing apparatus 1 for drying the wafers W having received the chemical reaction treatment and cleaned, an unloader 305 disposed downstream of the drying tanks 303 for receiving treated wafers W, a first transport mechanism 309 for transporting the wafers W between the loader 301 and each external transfer position 307, a second transport mechanism 311 for transporting the wafers W between each external transfer position 307 and the drying tanks 303, and a third transport mechanism 313 for transporting the wafers W between the three drying tanks 303 and the unloader 305.

Aligning racks 131 are constructed movable between the anodizing apparatus 1 and a transport path of the first transport mechanism 309. Specifically, aligning rack moving mechanisms 317 are provided each for moving the aligning rack 131 between a transfer position 315 adjacent the anodizing apparatus 1 and an external transfer position 307 adjacent the transport path of the first transport mechanism 309. A cleaning mechanism 319 is provided along a moving path of each aligning rack 131.

The cleaning mechanism 319 supplies a cleaning liquid such as deionized water to the aligning rack 131. Supply of the cleaning liquid is carried out from a point of time when the treated wafers W are placed on the aligning rack 131 until the aligning rack 131 is moved to the external transfer position 307. This supply of the cleaning liquid can clean the treated wafers W unloaded from the anodizing apparatus 1 to the aligning rack 131 in the transfer position 315. This can save the time and trouble taken in moving the wafers W to the cleaning tank 205 as in the anodizing system 51, thereby to improve the throughput. Further, the time for which the electrolyte solution remains adhering to the wafers W can be made constant, which realizes a constant finished state of the wafers W.

This invention is not limited to the foregoing embodiments, but may be modified as follows:

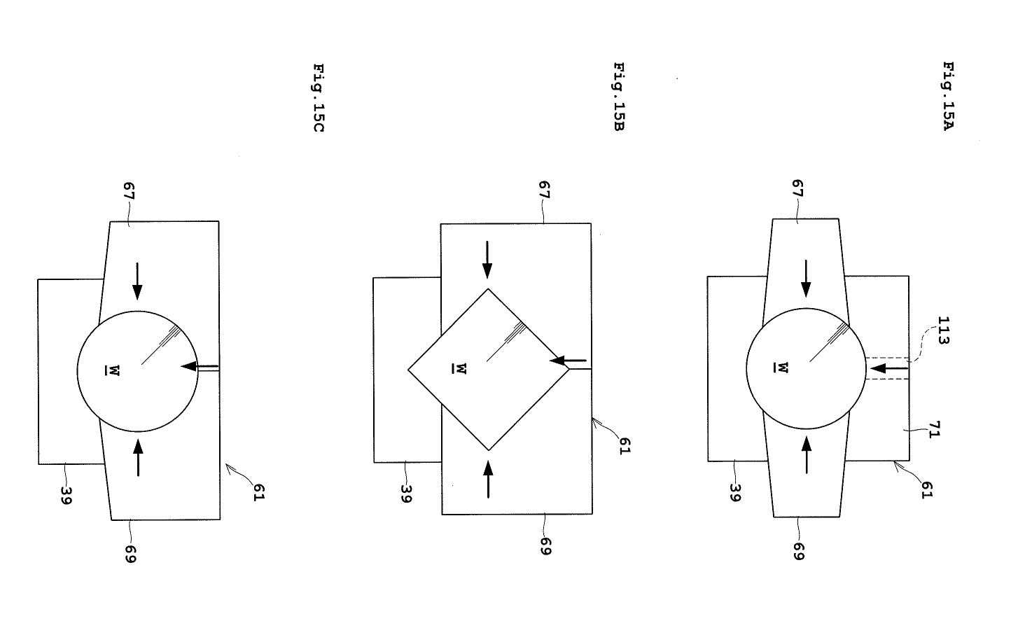

(1) The shape of the wafers W which can be treated with this apparatus need not be square as in the foregoing embodiments. Uniform porous layers can be formed similarly on the front and back surfaces of circular substrates generally used in manufacturing integrated circuits and having a notch or what is called an orientation flat indicating a surface orientation of each substrate, by adapting the shapes of the holders and the like which surround the substrates. As shown in a schematic front view of FIG. 15A, for example, circular wafers W can be treated when the left holder unit 67, right holder unit 69 and upper holder unit 71 constituting the upper holder 61, and the lower holder 39, of the anodizing apparatus are shaped to match the circumferences of the circular wafers W.

Although not shown, also to substrates of any shapes such as polygonal, oblong and elliptical, the anodizing apparatus of this mode is applicable for treating such, and the substrates of those shapes having porous layers formed thereon can be obtained.

(2) In the anodizing apparatus 1 according to the foregoing embodiments, the holding device includes the three members of upper holder unit 71, left holder unit 67 and right holder unit 69. However, this invention is not limited to the holding device of such construction. For example, the holding device may be constructed to have a left holder unit and a right holder unit like clippers directed downward.

Specifically, as shown in schematic front views of FIGS. 15B and 15C, for example, the upper holder 61 may consist mainly of two members, i.e. a left holder unit 67 and a right holder unit 69. In this case, the left holder unit 67 and right holder unit 69 can transport a plurality of wafers W in liquid-tight contact with the circumferential surfaces thereof, and are shaped to complete a liquid-tight closure of the entire circumferential surfaces of the wafers W in cooperation with the lower holder 39 at the time of treatment. These FIGS. 15A, 15B and 15C are schematic views illustrating rough shapes of the constituents, and details of each part are omitted. It is needless to say that the illustrated examples include, as appropriate, the elastic members, exhaust passages and so on described in the foregoing embodiments.

(3) In the anodizing apparatus 1 according to the foregoing embodiments, the square wafers W under treatment are held such that each has one pair of corners vertically opposed to each other and the other pair of corners horizontally opposed. However, this invention is not limited to such holding position. For example, the square wafers W may be held in a position in which two opposed sides of each are horizontal.

(4) The anodizing apparatus 1 according to the foregoing embodiments is directed to treatment of square wafers W. This invention is applicable to treatment of wafers W shaped otherwise.

This invention may be embodied in other specific forms without departing from the spirit or essential attributes thereof and, accordingly, reference should be made to the appended claims, rather than to the foregoing specification, as indicating the scope of the invention.

What is claimed is:

1. An anodizing apparatus for causing an anodizing reaction to substrates immersed in an electrolyte solution, comprising:
a storage tank for storing the electrolyte solution;
a holding device for holding a plurality of substrates in liquid-tight contact with circumferential surfaces of the substrates;
a moving mechanism for moving the holding device between a transfer position outside the storage tank and a treating position inside the storage tank; and
a closing device disposed in the storage tank for cooperating with the holding device to complete a liquid-tight closure of the circumferential surfaces of the substrates held by the holding device;
wherein chemical reaction treatment is carried out with the circumferential surfaces of the substrates placed in a liquid-tight state by moving the holding device holding the substrates to the treating position, and operating the closing device, and after the chemical reaction treatment is completed, the closing device is made inoperative and the holding device is moved away from the treating position to unload the substrates from the storage tank.

2. The anodizing apparatus according to claim 1 wherein the holding device is arranged to hold the substrates as aligned at predetermined intervals.

3. The anodizing apparatus according to claim 2 wherein the storage tank has electrodes arranged adjacent one end and the other end in an aligning direction of the substrates held by the holding device, the electrodes being opposed to principal planes of substrates at opposite ends having the circumferential surfaces closed by the holding device and the closing device.

4. The anodizing apparatus according to claim 1 wherein the holding device includes a first holder unit for contacting one side of the circumferential surfaces of the substrates, a second holder unit for contacting the other side of the circumferential surfaces of the substrates, and an opening and closing driver for moving the first holder unit and the second holder unit toward each other to hold the substrates, and moving the first holder unit and the second holder unit away from each other to release the substrates.

5. The anodizing apparatus according to claim 2 wherein the holding device includes a first holder unit for contacting one side of the circumferential surfaces of the substrates, a second holder unit for contacting the other side of the circumferential surfaces of the substrates, and an opening and closing driver for moving the first holder unit and the second holder unit toward each other to hold the substrates, and moving the first holder unit and the second holder unit away from each other to release the substrates.

6. The anodizing apparatus according to claim 3 wherein the holding device includes a first holder unit for contacting one side of the circumferential surfaces of the substrates, a second holder unit for contacting the other side of the circumferential surfaces of the substrates, and an opening and closing driver for moving the first holder unit and the second holder unit toward each other to hold the substrates, and moving the first holder unit and the second holder unit away from each other to release the substrates.

7. The anodizing apparatus according to claim 1 wherein the closing device has a closing member for contacting, in a liquid-tight state, parts of the circumferential surfaces of the substrates left out of contact with the holding device.

8. The anodizing apparatus according to claim 7 wherein the closing device includes a first closing member fixed inside the storage tank.

9. The anodizing apparatus according to claim 7 wherein the closing device includes a second closing member for pressing upon the circumferential surfaces of the substrates held by the holding device to maintain the liquid-tight state.

10. The anodizing apparatus according to claim 1 wherein the holding device and the closing device have elastic members as parts thereof for contacting the circumferential surfaces of the substrates.

11. The anodizing apparatus according to claim 10 wherein the elastic members have an electrical insulating property, and the parts for contacting the substrates are formed uniformly over the entire circumferential surfaces of the substrates.

12. The anodizing apparatus according to claim 10 wherein each of the elastic members has a two-layer structure including a first member located to face the circumferential surfaces of the substrates, and a second member located outside the first member, the first member having a smaller coefficient of elasticity than the second member.

13. The anodizing apparatus according to claim 9 further comprising a pressing mechanism for pressing the second closing member upon the first holder unit and the second holder unit in the treating position.

14. The anodizing apparatus according to claim 13 wherein:
the first holder unit and/or the second holder unit have/has a first slope or slopes formed thereon and inclined outward and downward;
the second closing member has a second slope or slopes formed in a position or positions corresponding to the first slope or slopes and inclined outward and downward; and
when the second closing member is pressed upon the first holder unit and/or the second holder unit in the treating position, the first slope or slopes and the second slope or slopes engage each other to push the first holder unit and the second holder unit toward each other.

15. The anodizing apparatus according to claim 13 wherein:
the first holder unit and/or the second holder unit have/has a third slope or slopes formed thereon and inclined outward and upward;
the first closing member has a fourth slope or slopes formed in a position or positions corresponding to the third slope or slopes and inclined outward and upward; and
when the second closing member is pressed upon the first holder unit and/or the second holder unit in the treating position, the first holder unit and/or the second holder unit is/are pressed upon the first closing member, and the third slope or slopes and the fourth slope or slopes engage each other to push the first holder unit and the second holder unit toward each other.

16. The anodizing apparatus according to claim 3 wherein each of the electrodes is formed of highly compact, high-density, high-purity carbon.

17. The anodizing apparatus according to claim 9 wherein:
the second closing member has a plurality of exhaust passages formed between the substrates in plan view, and extending from an inner ceiling surface to an outer surface of the second closing member, with upper openings located above a liquid level in the storage tank; and
the elastic member has a plurality of elastic member passages formed in positions corresponding to the exhaust passages to communicate with the exhaust passages.

18. The anodizing apparatus according to claim 17 wherein:
the second closing member has an exhaust passage block between the inner ceiling surface and an upper surface of the elastic member;
the exhaust passage block including a plate-like member having a plurality of block passages formed therein and communicating with the exhaust passages and the elastic member passages, and partitions formed on the plate-like member as arranged between the block passages and projecting toward the elastic member, with only lower ends of the partitions thrust into the elastic member.

19. The anodizing apparatus according to claim 13 further comprising a switching circuit for alternately switching polarities of direct voltage to the electrode adjacent one end and the electrode adjacent the other end.

20. The anodizing apparatus according to claim 1 further comprising:
an aligning rack for supporting the substrates as aligned parallel to one another; and
an aligning rack moving mechanism for moving the aligning rack between the transfer position and an external transfer position different from the transfer position;
wherein the moving mechanism transports the substrates to the storage tank after the holding device receives the substrates from the aligning rack in the transfer position.

21. The anodizing apparatus according to claim 20 further comprising a cleaning mechanism disposed adjacent a moving path of the aligning rack moving mechanism for supplying a cleaning liquid to the substrates on the aligning rack in the moving path.

22. An anodizing system comprising:
the anodizing apparatus according to claim 1;
a standby tank disposed adjacent and upstream of the anodizing apparatus and having the aligning table;
a loader disposed upstream of the standby tank for storing substrates to be treated;
a cleaning tank disposed downstream of the anodizing apparatus for cleaning the substrates having received chemical reaction treatment;
a drying tank disposed downstream of the cleaning tank for drying the substrate cleaned;
an unloader disposed downstream of the drying tank for receiving the substrates treated;
a first transport mechanism for transporting the substrates between the loader and the standby tank;
a second transport mechanism having the holding device and the moving mechanism for transporting the substrates between the standby tank and the anodizing apparatus and between the anodizing apparatus and the cleaning tank;
a third transport mechanism for transporting the substrates between the cleaning tank and the drying tank; and
a fourth transport mechanism for transporting the substrates between the drying tank and the unloader.

23. An anodizing system comprising:
a plurality of the anodizing apparatus according to claim 21;
a loader disposed upstream of the plurality of the anodizing apparatus for storing substrates to be treated;
a drying tank disposed downstream of the plurality of the anodizing apparatus for drying the substrates having received chemical reaction treatment and cleaned;
an unloader disposed downstream of the drying tank for receiving the substrates treated;
a first transport mechanism for transporting the substrates between the loader and each external transfer position;
a second transport mechanism for transporting the substrates between the each external transfer position and the drying tank; and
a third transport mechanism for transporting the substrates between the drying tank and the unloader.

24. An anodizing apparatus for causing an anodizing reaction to substrates immersed in an electrolyte solution, comprising:
a storage tank for storing the electrolyte solution;
a holding device for forming a hollow portion therein having a section of similar shape to the substrates, and holding the substrates with circumferential surfaces of the respective substrates placed in a liquid-tight state;
a pair of electrodes arranged at opposite ends of the hollow portion formed in the holding device;
an electric circuit for applying direct current to the pair of electrodes; and
a moving mechanism for moving the holding device between a transfer position outside the storage tank and a treating position inside the storage tank;
wherein chemical reaction treatment is carried out with the circumferential surfaces of the substrates placed in the liquid-tight state and electrically separated and insulated, by moving the holding device holding the substrates to the treating position, and filling the hollow portion with the electrolyte solution, and after the chemical reaction treatment is completed, the holding device is moved from the treating position to unload the substrates from the storage tank.

25. A semiconductor wafer having porous layers of uniform thickness, pore size and pore density formed over both front and back surfaces of the semiconductor wafer, by carrying out anodizing treatment using the anodizing apparatus according to claim 19.
